(19) United States
(12) Patent Application Publication
(10) Pub. No.: US 2021/0111314 A1
(43) Pub. Date: Apr. 15, 2021

(54) LED WHITE LIGHT DEVICE AND BACKLIGHT MODULE

(71) Applicant: TCL China Star Optoelectronics Technology Co., Ltd, Shenzhen, Guangdong (CN)

(72) Inventor: Bao ZHA, Shenzhen, Guangdong (CN)

(21) Appl. No.: 16/618,810

(22) PCT Filed: Nov. 12, 2019
(86) PCT No.: PCT/CN2019/117414

§ 371 Date: Dec. 3, 2019

(30) Foreign Application Priority Data
Oct. 14, 2019 (CN) 201910974584.5

(51) Int. Cl. H01L 33/50; C09B 11/24

(52) U.S. Cl. CPC H01L 33/504; H01L 33/507; C09B 11/24

(57) ABSTRACT

A light emitting diode (LED) white light device and a backlight module. The LED white light device includes a white light source and a purified film disposed on the white light source. The purified film is evenly distributed with a first rhodamine dye configured to transfer cyan light into green light and a second rhodamine dye configured to transfer orange light into red light.

### FIELD OF INVENTION

The present invention relates to a field of display panel technologies, especially to a light emitting diode (LED) white light device and a backlight module.

### BACKGROUND OF INVENTION

With the development of display technologies, wide color gamut has become an important developing direction. Wide color gamut means that a display device can display more abundant colors and have more color displaying capability, which can avoid distortion and color blocks during displaying. Because types of colors are increased, color switching in displayed images can be more natural, which makes the levels of the images more clear to perform more details and more real effects. For a light emitting diode (LED) liquid crystal television, because a screen thereof has no self-illumination characteristics, enhancing color gamut is mainly achieved by a three primary color filter and a backlight.

### SUMMARY OF INVENTION

### Technical Issue

At present, a way for enhancing purity of a backlight is to employ a backlight with blue light emitting diodes (LEDs) and red and green fluorescent materials, or to employ a quantum dot (QD) backlight technology. However, although the QD backlight technology can drastically improve the color gamut, heavy metal elements ingredients, poor heat stability, and a high cost of QDs are important factors that limit development of such technology. The biggest drawback using the blue LEDs and red and green fluorescent materials is that ultimately emitted three primary color lights of red, green, and blue are not pure. The reason is that during enhancement of color gamut no purification to the three primary color lights of red, green, and blue is implemented such that orange light and/or cyan light exist. Thus, the three primary color lights of red, green, and blue emitted therefrom are not pure.

### Technical Solution

To solve the above issue, the present invention provides technical solutions as follows.

An embodiment of the present invention provides an LED white light device and a backlight module to solve issues of in a backlight of a conventional display, three primary color lights of red, green, and blue are not pure and color gamut is narrow.

An embodiment of the present invention provides an LED white light device, comprising a white light source and a purified film disposed on the white light source;

a first rhodamine dye distributed evenly in the purified film and configured to transfer cyan light into green light, and a second rhodamine dye distributed evenly in the purified film and configured to transfer orange light into red light.

In the LED white light device of an embodiment of the present invention, the first rhodamine dye comprises a rhodamine 6G derivative having a chemical structure with a chemical structural formula (1) as follows:

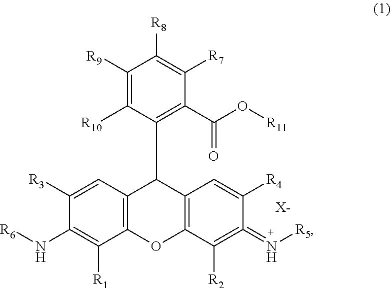

wherein X⁻ is selected from one of F⁻, Cl⁻, Br⁻, CN⁻, ClO₄⁻, CF₃SO₃⁻, CF₂HSO₃⁻, and CFH₂SO₃⁻;

wherein R₁-R₄ are independently selected from one of —F, —Cl, —Br, —I, —CN, a non-conjugate structure, and a conjugate structure connected through an alkoxy group or an ester group;

wherein R₅-R₆ are selected from one of a non-conjugate structure, and a conjugate structure connected through an alkoxy group or an ester group;

wherein R₇-R₁₀ are independently selected from one of —F, —Cl, —Br, —I, —CN, a non-conjugate structure, and a conjugate structure connected through an alkoxy group or an ester group; and

wherein R₁₁ is selected from one of —F, —Cl, —Br, —I, —CN, a structure having a non-conjugate group, a structure having a conjugate structure connected through an alkoxy group or an ester group, and a chemical structure with a chemical structural formula (2) as follows;

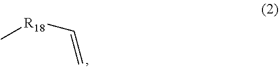

R₁₈ are selected from one of a non-conjugate structure, and a conjugate structure connected through an alkoxy group or an ester group.

In the LED white light device of an embodiment of the present invention, in the chemical structure with a chemical structural formula (1) the conjugate structure comprises a chemical structure with a chemical structural formula (3) as follows:

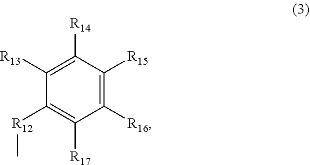

wherein R₁₂ is selected from one of an oxygen-containing connecting group; and

wherein R₁₃-R₁₇ are independently selected from one of a non-conjugate structure, and a conjugate structure connected through an alkoxy group or an ester group.

In the LED white light device of an embodiment of the present invention, in the chemical structure with a chemical structural formula (1) the conjugate structure is independently selected from one of a five-membered heterocyclic compound, a six-membered heterocyclic compound, and a benzoheterocyclic compound,

wherein the five-membered heterocyclic compound is furan, thiophene, pyrrole, thiazole, or imidazole, and the six-membered heterocyclic compound is pyridine, pyrazine, pyrimidine, pyridazine, indole, quinoline, pteridine, or acridine.

In the LED white light device of an embodiment of the present invention, the second rhodamine dye comprises a rhodamine 101 derivative as shown in a chemical structure with a chemical structural formula (4) as follows:

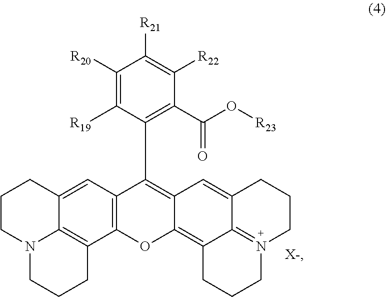

wherein X⁻ is selected from one of F⁻, Cl⁻, Br⁻, CN⁻, ClO₄⁻, CF₃SO₃⁻, CF₂HSO₃⁻, and CFH₂SO₃⁻;

wherein R₁₉-R₂₂ are independently selected from one of —F, —Cl, —Br, —I, —CN, —NH2, —COOH, —OH, —SH, —COCl, —COBr, —CN, —NO₂, —NH₂, a benzene or phenol ring, a non-conjugate structure, and a conjugate structure connected through an alkoxy group or an ester group; and

wherein R₂₃ are selected from one of a non-conjugate structure, and a chemical structure with a chemical structural formula (5) as follows:

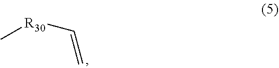

wherein R₃₀ are selected from one of a non-conjugate structure and a conjugate structure connected through an alkoxy group or an ester group.

In the LED white light device of an embodiment of the present invention, in the chemical structure with a chemical structural formula (4) the conjugate structure comprises a chemical structure with a chemical structural formula (6) as follows:

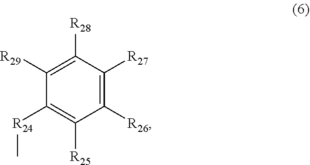

wherein R₂₄ is selected from one of an oxygen-containing connecting group; and

wherein R₂₅-R₂₉ are independently selected from one of a non-conjugate structure, and a conjugate structure connected through an alkoxy group or an ester group.

In the LED white light device of an embodiment of the present invention, in the chemical structure with a chemical structural formula (4) the conjugate structure is independently selected from one of a five-membered heterocyclic compound, a six-membered heterocyclic compound, and a benzoheterocyclic compound;

wherein the five-membered heterocyclic compound is furan, thiophene, pyrrole, thiazole, or imidazole, and the six-membered heterocyclic compound is pyridine, pyrazine, pyrimidine, pyridazine, indole, quinoline, pteridine, or acridine.

In the LED white light device of an embodiment of the present invention, material of the purified film is transparent resin or pressure sensitive adhesive, and the first rhodamine dye and the second rhodamine dye are distributed evenly in the transparent resin or the pressure sensitive adhesive.

In the LED white light device of an embodiment of the present invention, the white light source comprises a blue light chip and yellow phosphor covering the blue light chip.

In the LED white light device of an embodiment of the present invention, a thickness of the purified film is 1-100 um.

In the LED white light device of an embodiment of the present invention, a range of a wavelength of the cyan light transferred by the first rhodamine dye is 480 nm-510 nm.

In the LED white light device of an embodiment of the present invention, a range of a wavelength of the orange light transferred by the second rhodamine dye is 570 nm-610 nm.

In the LED white light device of an embodiment of the present invention, a mass percentage of the first rhodamine dye in the purified film is 1%-5%.

In the LED white light device of an embodiment of the present invention, a mass percentage of the second rhodamine dye in the purified film is 1%-5%.

According to the above objective of the present invention, an embodiment of the present invention also provides a backlight module comprising the above LED white light device.

### Advantages

Advantages of the present invention is that: the present invention provides an LED white light device and a backlight module, comprising a white light source and a purified film disposed on the white light source. By the first rhodamine dye configured to transfer cyan light into green light and the second rhodamine dye configured to transfer orange light into red light in the purified film, the cyan light and the orange light in the white light source is absorbed and purified into red light and yellow light, which not only enhances color purity of the backlight, but also improves a use rate of a light source and achieves an objective of power saving.

### DESCRIPTION OF DRAWINGS

To more clearly elaborate on the technical solutions of embodiments of the present invention or prior art, appended figures necessary for describing the embodiments of the present invention or prior art will be briefly introduced as follows. Apparently, the following appended figures are merely some embodiments of the present invention. A person of ordinary skill in the art may acquire other figures according to the appended figures without any creative effort.

FIG. 1 is a schematic structural view of a light emitting diode (LED) white light device provided by an embodiment of the present invention;

FIG. 2 is a schematic view of a pure color transferring mechanism of a backlight; and

FIG. 3 is a flowchart of a LED white light device provided by an embodiment of the present invention.

### DETAILED DESCRIPTION OF PREFERRED EMBODIMENTS

The specific structural and functional details disclosed herein are merely representative and are intended to describe the exemplary embodiment of the present invention. However, the present invention may be embodied in many alternative forms and should not be construed to only be limited by the embodiment described here.

In the description of the present invention, it is to be understood that orientation or positional relationships indicated by terms “center”, “lateral”, “upper”, “lower”, “left”, “right”, “vertical”, “horizontal”, “top” “bottom”, “inside”, “outside”, etc., are based on the orientation or positional relationship shown in the drawings, and are merely for convenience of describing the present invention and simplifying the description, rather than indicating or implying that the device or component must have a specific orientation and be configured and operated in a specific orientation, and therefore they cannot be understood as limitations to the present invention. Furthermore, the terms “first” and “second” are used for descriptive purposes only and are not to be construed as indicating or implying a relative importance or implicitly indicating the number of technical features indicated. Thus, a feature defining “first”, “second” may explicitly or implicitly include one or more of the characteristics. In the description of the present invention, unless otherwise stated, “a plurality of” means two or more. In addition, the term “comprise” and any variant thereof is intended to cover non-exclusive inclusion.

In the description of the present invention, it should be noted that unless clear rules and limitations otherwise exist, terminologies “install”, “connect”, “connection” should be understood in a broad sense. For instance, the connection can be a fixed connection, a detachable connection or an integral connection. The connection can be a mechanical connection, an electrical connection or a telecommunication. The connection can be a direct connection, an indirect connection through an intermedium, can be an internal communication between two elements or an interaction between the two elements. For a person of ordinary skill in the art, the specific meaning of the above terminology in the present invention can be understood on a case-by-case basis.

The terminology used herein is only for the purpose of describing the particular embodiments instead of limiting exemplary embodiments. The singular forms “a”, “an” also includes plural forms unless it is specified otherwise in the context. It is also to be understood that the terms “comprises” and/or “comprising”, as used herein, are intended to mean the presence of the recited features, integers, steps, operations, units and/or components, and do not exclude the presence or addition of one or more other features, integers, steps, operations, units, components, and/or combinations thereof.

The present invention will be described with accompanying drawings and embodiments as follows.

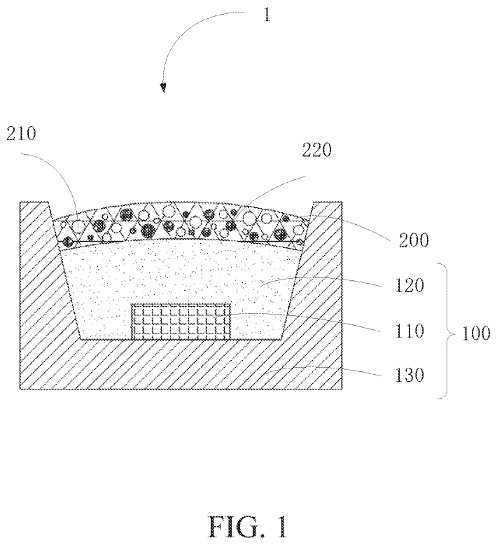

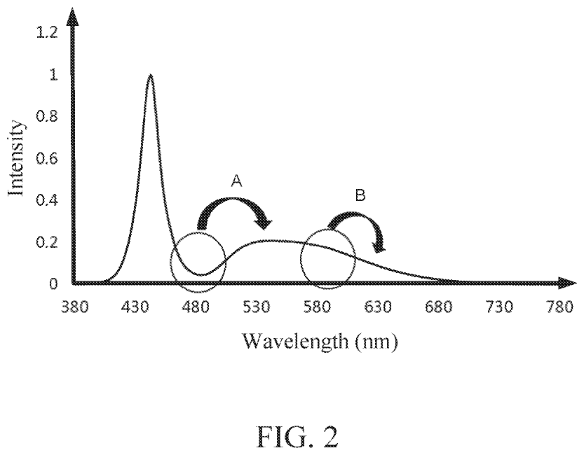

With reference to FIGS. 1 and 2, an embodiment of the present invention provides a light emitting diode (LED) white light device 1 comprising a white light source 100 and a purified film 200 disposed on the white light source 100.

A first rhodamine dye 210 is distributed evenly in the purified film 200 and is configured to transfer cyan light into green light, and a second rhodamine dye 220 I distributed evenly in the purified film 200 and is configured to transfer orange light into red light.

It should be understood that the white light source 100 in the present invention can be one of known devices for generating white light adapted for display panels. Specifically, as shown in FIG. 1, the white light source 100 comprises a blue light chip 110 and yellow phosphor 120 covering the blue light chip 110. Specifically, the white light source 100 can further comprise a base 130, and the blue light chip 110 and the yellow phosphor 120 are disposed in the base 130. Of course, in a specific structure, a portion corresponding to the yellow phosphor 120 can be replaced with a film layer including the yellow phosphor 120, and no limitation is thereto, Furthermore, In an embodiment, a thickness of the purified film 200 is 1-100 um, material of the purified film 200 is transparent resin or a pressure sensitive adhesive, and both the first rhodamine dye 210 and the second rhodamine dye 220 are distributed evenly in the transparent resin or the pressure sensitive adhesive.

As described above, a first rhodamine dye 210 is distributed evenly in the purified film 200 and is configured to transfer cyan light into green light, and a second rhodamine dye 220 is distributed evenly in the purified film 200 and is configured to transfer orange light into red light, as shown in FIG. 1. Schematically, structures of the first rhodamine dye 210 and the second rhodamine dye 220 are in form of particles in FIG. 1, but specifically existing form thereof in the purified film 200 is not limited. The first rhodamine dye 210 absorbs and transfers cyan light in white light emitted from the white light source 100 into green light and emit the green light. The second rhodamine dye 220 absorbs and transfers orange light in the white light emitted from the white light source 100 into red light and emit the red light. Specifically, as shown in FIG. 2, a range of a wavelength of the cyan light absorbed in a place A can be 480-510 nm. A range of a wavelength of the orange light absorbed in a place B can be 570-610 nm.

In an embodiment, the first rhodamine dye 210 comprises a rhodamine 6G derivative having a chemical structure with a chemical structural formula (1) as follows:

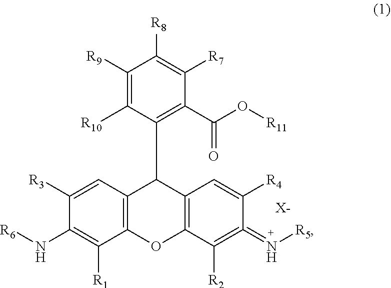

X⁻ is selected from one of F⁻, Cl⁻, Br⁻, CN⁻, ClO₄⁻, CF₃SO₃⁻, CF₂HSO₃⁻, and CFH₂SO₃⁻.

R₁-R₄ are independently selected from one of —F, —Cl, —Br, —I, —CN, a non-conjugate structure, and a conjugate structure connected through an alkoxy group or an ester group.

R₅-R₆ are selected from one of a non-conjugate structure, and a conjugate structure connected through an alkoxy group or an ester group.

R₇-R₁₀ are independently selected from one of —F, —Cl, —Br, —I, —CN, a non-conjugate structure, and a conjugate structure connected through an alkoxy group or an ester group.

R₁₁ is selected from one of —F, —Cl, —Br, —I, —CN, a structure having a non-conjugate group, a structure having a conjugate structure connected through an alkoxy group or an ester group, and a chemical structure with a chemical structural formula (2) as follows:

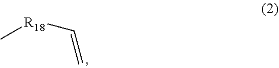

R₁₈ are selected from one of a non-conjugate structure, and a conjugate structure connected through an alkoxy group or an ester group.

The conjugate structure can be a compound including heterocycle, and the compound including heterocycle is a five-membered heterocyclic compound, a six-membered heterocyclic compound, and a benzoheterocyclic compound, wherein the five-membered heterocyclic compound can be furan, thiophene, pyrrole, thiazole, or imidazole. The six-membered heterocyclic compound can be pyridine, pyrazine, pyrimidine, pyridazine, indole, quinoline, pteridine, or acridine. The non-conjugate structure can be linear alkane, branched alkane, linear or branched alkane containing an alkoxy group, a chain object including an ester group, a alkane derivative replaced with fluorine, and a carbon chain thereof comprises 1-25 carbon atoms.

For example, in the chemical structure with a chemical structural formula (1) the conjugate structure comprises a chemical structure with a chemical structural formula (3) as follows:

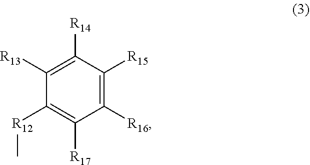

R₁₂ are selected from one of an oxygen-containing connecting group, the oxygen-containing connecting group can be an alkoxy group or an ester group. a carbon chain comprises 1-25 carbon atoms. R₁₃-R₁₇ are independently selected from one of a non-conjugate structure, and a conjugate structure connected through an alkoxy group or an ester group. the non-conjugate structure can be linear alkane, branched alkane, linear or branched alkane containing an alkoxy group, a chain object including an ester group, a alkane derivative replaced with fluorine, and a carbon chain thereof comprises 1-25 carbon atoms. R₁₃-R₁₇ can also have a benzene ring, an unsaturated ring-like substance, or a chain structure connected thereto and having a different length.

In an embodiment, the second rhodamine dye 220 comprises a rhodamine 101 derivative as shown in a chemical structure with a chemical structural formula (4) as follows:

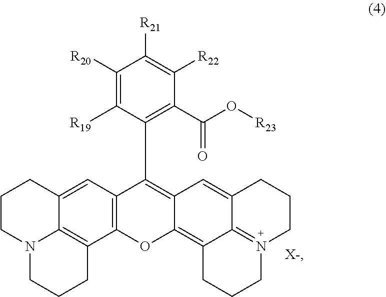

X⁻ is selected from one of F⁻, Cl⁻, Br⁻, CN⁻, ClO₄⁻, CF₃SO₃⁻, CF₂HSO₃⁻, and CFH₂SO₃⁻. R₁₉-R₂₂ are independently selected from one of —F, —Cl, —Br, —I, —CN, —NH₂, —COOH, —OH, —SH, —COCl, —COBr, —CN, —NO₂, —NH₂, benzene, and phenol ring, a non-conjugate structure, and a conjugate structure connected through an alkoxy group or an ester group.

R₂₃ are selected from one of a non-conjugate structure and a chemical structure with a chemical structural formula (5):

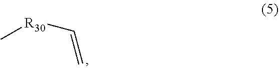

R₃₀ are selected from one of a non-conjugate structure, and a conjugate structure connected through an alkoxy group or an ester group.

The conjugate structure can be a compound including heterocycle, and the compound including heterocycle is a five-membered heterocyclic compound, a six-membered heterocyclic compound, or a benzoheterocyclic compound. The five-membered heterocyclic compound can be furan, thiophene, pyrrole, thiazole, or imidazole, and the six-membered heterocyclic compound can be pyridine, pyrazine, pyrimidine, pyridazine, indole, quinoline, pteridine, or acridine. The non-conjugate structure can be linear alkane, branched alkane, linear or branched alkane containing an alkoxy group, a chain object including an ester group, or an alkane derivative replaced with fluorine, and a carbon chain thereof comprises 1-30 carbon atoms.

For example, in the chemical structure with a chemical structural formula (4) the conjugate structure comprises a chemical structure with a chemical structural formula (6) as follows:

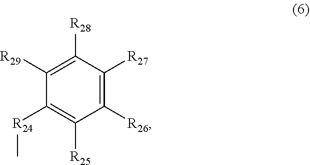

R₂₄ is selected from one of an oxygen-containing connecting group, and the oxygen-containing connecting group can be an alkoxy group or an ester group. R₂₅-R₂₉ are independently selected from one of a non-conjugate structure, and a conjugate structure connected through an alkoxy group or an ester group. the non-conjugate structure can be linear alkane, branched alkane, linear or branched alkane containing an alkoxy group, a chain object including an ester group, a alkane derivative replaced with fluorine, a carbon chain comprises 1-25 carbon atoms. R₂₅-R₂₉ can also have a benzene ring, an unsaturated ring-like substance, or a chain structure connected thereto and having a different length.

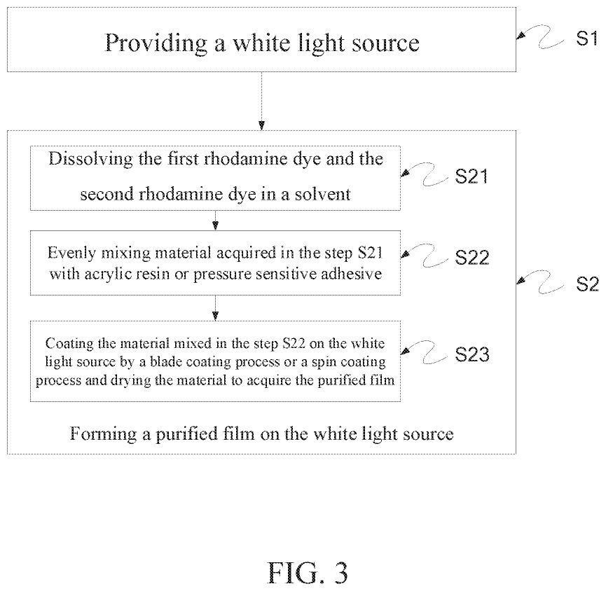

The present invention also provides a LED white light device 1 manufacturing method as shown in FIG. 3, comprising steps as follows.

A step S1 provides a white light source 100.

A step S2 forms a purified film 200 on the white light source 100. A first rhodamine dye 210 is distributed evenly in the purified film 200 and is configured to transfer cyan light into green light, and a second rhodamine dye 220 is distributed evenly in the purified film 200 and is configured to transfer orange light into red light.

The step forming a purified film 200 on the white light source 100 comprises a step S21 and a step S22.

The step S21 dissolves the first rhodamine dye 210 and the second rhodamine dye 220 in a solvent.

The solvent can be methanol, ethanol, ethyl acetate, n-hexane, etc. Specifically, the first rhodamine dye 210 comprises the above rhodamine 6G derivative including the chemical structure with a chemical structural formula (1). the second rhodamine dye 220 comprises the above rhodamine 101 derivative including the chemical structure with a chemical structural formula (4). Furthermore, a mass percentage of each of the rhodamine 6G derivative and the rhodamine 101 derivative in the purified film 200 is 1%-5%.

A step S22 evenly mixes material acquired in the step S21 with acrylic resin or pressure sensitive adhesive.

A step S23 coats the material mixed in the step S22 on the white light source 100 by a blade coating process or a spin coating process and dries the material to acquire the purified film 200.

An embodiment of the present invention also provides a backlight module comprising the above LED white light device 1. Apparently, the backlight module can be applied to any display panel requiring a backlight part, by the first rhodamine dye 210 configured to transfer cyan light into green light and the second rhodamine dye 220 configured to transfer orange light into red light in the backlight module, to absorb and purify the cyan light and the orange light in the white light source 100 into red light and yellow light, which achieves objectives of wide color gamut, high purity, and high use rate of the light source. Furthermore, the backlight module in the present invention further comprises other structures such as an optical film and a light guide, which will not be described repeatedly herein.

As described above, the present invention provides an LED white light device 1 and a backlight module comprising a white light source 100 and a purified film 200 disposed on the white light source 100. By the first rhodamine dye 210 configured to transfer cyan light into green light and the second rhodamine dye 220 configured to transfer orange light into red light in the purified film 200, the cyan light and the orange light in the white light source 100 is absorbed and purified into red light and yellow light, which not only enhances color purity of the backlight, but also improves a use rate of a light source and achieves an objective of power saving.

Although the preferred embodiments of the present invention have been disclosed as above, the aforementioned preferred embodiments are not used to limit the present invention. The person of ordinary skill in the art may make various changes and modifications without departing from the spirit and scope of the present invention. Therefore, the scope of protection of the present invention is defined by the scope of the claims.

What is claimed is:

1. A light emitting diode (LED) white light device, comprising a white light source and a purified film disposed on the white light source;
a first rhodamine dye distributed evenly in the purified film and configured to transfer cyan light into green light, and a second rhodamine dye distributed evenly in the purified film and configured to transfer orange light into red light.

2. The LED white light device as claimed in claim 1, wherein the first rhodamine dye comprises a rhodamine 6G derivative having a chemical structure with a chemical structural formula (1) as follows: 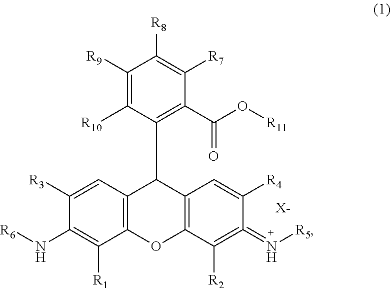
wherein X⁻ is selected from one of F⁻, Cl⁻, Br⁻, CN⁻, ClO₄⁻, CF₃SO₃⁻, CF₂HSO₃⁻, and CFH₂SO₃⁻;
wherein R₁-R₄ are independently selected from one of —F, —Cl, —Br, —I, —CN, a non-conjugate structure, and a conjugate structure connected through an alkoxy group or an ester group;
wherein R₅-R₆ are selected from one of a non-conjugate structure, and a conjugate structure connected through an alkoxy group or an ester group;
wherein R₇-R₁₀ are independently selected from one of —F, —Cl, —Br, —I, —CN, a non-conjugate structure, and a conjugate structure connected through an alkoxy group or an ester group; and
wherein R₁₁ is selected from one of —F, —Cl, —Br, —I, —CN, a structure having a non-conjugate group, a structure having a conjugate structure connected through an alkoxy group or an ester group, and a chemical structure with a chemical structural formula (2) as follows; 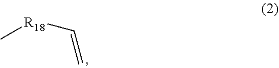
R₁₈ are selected from one of a non-conjugate structure, and a conjugate structure connected through an alkoxy group or an ester group.

3. The LED white light device as claimed in claim 2, wherein in the chemical structure with a chemical structural formula (1) the conjugate structure comprises a chemical structure with a chemical structural formula (3) as follows: 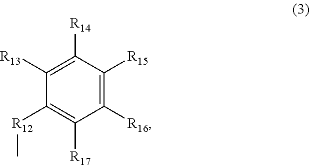
wherein R₁₂ is selected from one of an oxygen-containing connecting group; and
wherein R₁₃-R₁₇ are independently selected from one of a non-conjugate structure, and a conjugate structure connected through an alkoxy group or an ester group.

4. The LED white light device as claimed in claim 2, wherein in the chemical structure with a chemical structural formula (1) the conjugate structure is independently selected from one of a five-membered heterocyclic compound, a six-membered heterocyclic compound, and a benzoheterocyclic compound,
wherein the five-membered heterocyclic compound is furan, thiophene, pyrrole, thiazole, or imidazole, and the six-membered heterocyclic compound is pyridine, pyrazine, pyrimidine, pyridazine, indole, quinoline, pteridine, or acridine.

5. The LED white light device as claimed in claim 1, wherein the second rhodamine dye comprises a rhodamine 101 derivative as shown in a chemical structure with a chemical structural formula (4) as follows: 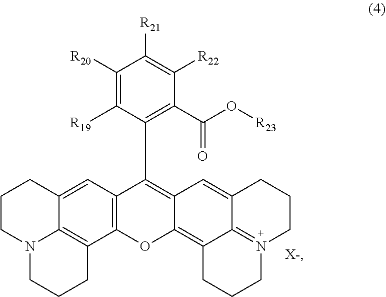
wherein X⁻ is selected from one of F⁻, Cl⁻, Br⁻, CN⁻, ClO₄⁻, CF₃SO₃⁻, CF₂HSO₃⁻, and CFH₂SO₃⁻;
wherein R₁₉-R₂₂ are independently selected from one of —F, —Cl, —Br, —I, —CN, —NH2, —COOH, —OH, —SH, —COCl, —COBr, —CN, —NO₂, —NH₂, a benzene or phenol ring, a non-conjugate structure, and a conjugate structure connected through an alkoxy group or an ester group; and
wherein R₂₃ are selected from one of a non-conjugate structure, and a chemical structure with a chemical structural formula (5) as follows: 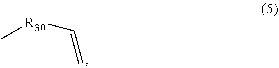
wherein R₃₀ are selected from one of a non-conjugate structure and a conjugate structure connected through an alkoxy group or an ester group.

6. The LED white light device as claimed in claim 5, wherein in the chemical structure with a chemical structural formula (4) the conjugate structure comprises a chemical structure with a chemical structural formula (6) as follows: 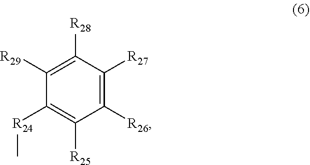
wherein R₂₄ is selected from one of an oxygen-containing connecting group; and
wherein R₂₅-R₂₉ are independently selected from one of a non-conjugate structure, and a conjugate structure connected through an alkoxy group or an ester group.

7. The LED white light device as claimed in claim 5, wherein in the chemical structure with a chemical structural formula (4) the conjugate structure is independently selected from one of a five-membered heterocyclic compound, a six-membered heterocyclic compound, and a benzoheterocyclic compound;
wherein the five-membered heterocyclic compound is furan, thiophene, pyrrole, thiazole, or imidazole, and the six-membered heterocyclic compound is pyridine, pyrazine, pyrimidine, pyridazine, indole, quinoline, pteridine, or acridine.

8. The LED white light device as claimed in claim 1, wherein material of the purified film is transparent resin or pressure sensitive adhesive, and the first rhodamine dye and the second rhodamine dye are distributed evenly in the transparent resin or the pressure sensitive adhesive.

9. The LED white light device as claimed in claim 1, wherein the white light source comprises a blue light chip and yellow phosphor covering the blue light chip.

10. The LED white light device as claimed in claim 1, wherein a thickness of the purified film is 1-100 um.

11. The LED white light device as claimed in claim 1, wherein a range of a wavelength of the cyan light transferred by the first rhodamine dye is 480 nm-510 nm.

12. The LED white light device as claimed in claim 1, wherein a range of a wavelength of the orange light transferred by the second rhodamine dye is 570 nm-610 nm.

13. The LED white light device as claimed in claim 1, wherein a mass percentage of the first rhodamine dye in the purified film is 1%-5%.

14. The LED white light device as claimed in claim 1, wherein a mass percentage of the second rhodamine dye in the purified film is 1%-5%.

15. A backlight module, comprising the LED white light device as claimed in claim 1.
